(19) United States
(12) Patent Application Publication
(10) Pub. No.: US 2014/0348622 A1
(43) Pub. Date: Nov. 27, 2014

(54) WAFER TRANSPORT APPARATUS

(71) Applicants: Katsuhiro Yamazoe, Okayama (JP); Shinichi Imai, Okayama (JP); Kosuke Sakata, Okayama (JP); Yoshiki Nishijima, Okayama (JP); Hiroaki Tsukimoto, Okayama (JP)

(72) Inventors: Katsuhiro Yamazoe, Okayama (JP); Shinichi Imai, Okayama (JP); Kosuke Sakata, Okayama (JP); Yoshiki Nishijima, Okayama (JP); Hiroaki Tsukimoto, Okayama (JP)

(73) Assignee: TAZMO CO., LTD., Okayama (JP)

(21) Appl. No.: 14/365,419

(22) PCT Filed: Dec. 15, 2011
(86) PCT No.: PCT/JP2011/079029

§ 371 Date: Jun. 13, 2014

(51) Int. Cl. H01L 21/67; B25J 11/00

(52) U.S. Cl. CPC H01L 21/67265; B25J 11/0095
USPC 414/744.2

(57) ABSTRACT

An object is to make it possible to adequately reduce the wafer transport time and to contribute to size-reduction of the semiconductor processing system.

Two wafer supports (3, 4) on which wafers (100) are placed are arranged to be apart from each other by a distance (D) in a vertical direction . To transport two wafers (100) to respective loading stages (200A, 200B), first a wafer (100) placed on the lower wafer support (3) is subjected to correction of its position in its main plane, and the wafer supports (3, 4) are descended. After the wafer (100) placed on the wafer support (3) is loaded onto pins (211-213), another wafer (100) placed on the upper wafer support (4) is subjected to correction of its position in its main plane, and the wafer supports (3, 4) are descended.

### TECHNICAL FIELD

The present invention relates to a wafer transport apparatus which transports a plurality of wafers at a time by holding them with a single handling arm, and accurately corrects a position of each of the plurality of wafers in its main plane during transporting.

### BACKGROUND ART

It is required for a wafer transport apparatus used for manufacturing a semiconductor to load a wafer accurately to a predetermined loading position in the main plane of the wafer. A conventional wafer transport apparatus has a transport robot which holds a wafer on a wafer support of a handling arm and transports the wafer from an unloading position to a loading position, and an alignment device which corrects the position of the wafer on the wafer support (see, for example, Patent Literature 1).

The transport robot holds a wafer on the wafer support at the unloading position, and places the wafer on a table of the alignment device. The alignment device detects the position of the wafer on the table, and corrects the relative positional relationship between the wafer and the wafer support so that the handling arm can load the wafer accurately to the loading position. The transport robot takes the position-corrected wafer from the table to the wafer support, and loads the wafer to the loading position.

On the other hand, there is a transport robot configuring a conventional wafer transport apparatus which has a plurality of wafer supports on a single handling arm so as to be capable of transporting a plurality of wafers at a time. This robot can transport a plurality of wafers at a time while the handling arm moves from an unloading position to a loading position.

### CITATION LIST

### Patent Literature

[Patent Literature 1]

Japanese Patent Unexamined Publication No. 2009-049251

### SUMMARY OF INVENTION

### Technical Problem

However, in the conventional wafer transport apparatus, it is necessary to correct the relative positions of the plurality of wafer supports to the respective wafers by using the alignment device. For this reason, the transfer of a wafer between each of the wafer supports and the table of the alignment device must be repeated plural times while the handling arm moves from the unloading position to the loading position. Accordingly, the wafer transport time cannot adequately be reduced.

Further, since the conventional wafer transport apparatus has the transport robot and the alignment device, the semiconductor processing system, to which the wafer transport apparatus is applied, becomes large in size.

An object of the present invention is to provide a wafer transport apparatus that can adequately reduce the wafer transport time and can contribute to down-sizing of the semiconductor processing systems.

### Solution to Problem

A wafer transport apparatus according to the present invention includes a main body, a handling arm, a plurality of wafer supports, a plurality of detection units, and a control unit. Each of the plurality of wafer supports holds a single wafer. The handling arm supports the plurality of wafer supports. The main body supports the handling arm movably at least in a main plane of each wafer. The plurality of detection units detect positions of wafers in their main planes at a plurality of loading stages, respectively. Based on detection results of the detection units, the control unit corrects positions in the main planes of the wafers respectively held by the plurality of wafer supports sequentially at different heights from one another at the loading stages.

According to this configuration, the plurality of wafers are sequentially subjected to correction of their positions in their main planes at different heights from one another at the loading stages, and loaded onto the respective plurality of loading stages. Since the plurality of wafers are transported to the respective loading stages at a time, and then sequentially corrected their positions in the main planes, they are not necessary to be moved repeatedly outside the loading stages. In addition, it is not necessary to install outside of the loading stages an alignment device for correcting the positions of the wafers in the main planes.

In this configuration, it is preferable that the control unit corrects the plurality of wafers sequentially from a lower wafer. In this manner, it is not necessary to move each of the plurality of wafers reciprocally in vertical directions in each of the loading stages, so that the time necessary to load the wafers can be minimized.

Also, it is preferable that the handling arm is liftably supported on the main body, and supports the plurality of wafer supports at different heights from one another. In this configuration, it is possible to easily and accurately load the plurality of wafers respectively onto a plurality of loading stages having a same height, by performing the correction of the position of a wafer in its main plane and then descending the handling arm sequentially from a wafer placed on a lower wafer support.

### Advantageous Effects of Invention

According to the present invention, a plurality of wafers can be accurately loaded to respective predetermined loading positions (loading stages), without moving the wafers repeatedly during the transfer from the unloading positions to the loading positions. Accordingly, the time for transporting the plurality of wafers can be adequately reduced. Further, it is not necessary to install an alignment device between the unloading positions and the loading positions. Accordingly, the present invention can contribute to size-reduction of the semiconductor processing system.

### BRIEF DESCRIPTION OF DRAWINGS

FIG. 1A and FIG. 1B are respectively a plan view and a side view showing a wafer transport apparatus according to a first embodiment of the present invention.

FIG. 2 is a plan view of the wafer transport apparatus during a loading operation.

FIG. 3 is a block diagram showing a control unit of the wafer transport apparatus.

FIG. 4 is a flowchart showing a processing procedure of the control unit.

FIG. 5A to FIG. 5E are diagrams showing operating states of the wafer transport apparatus.

FIG. 6 is a plan view showing a wafer transport apparatus according to a second embodiment of the present invention.

FIG. 7A and FIG. 7B are respectively a plan view and a side view showing a wafer transport apparatus according to a third embodiment of the present invention.

### DESCRIPTION OF EMBODIMENTS

Hereinafter, embodiments of wafer transport apparatus according to the present invention will be described with reference to the drawings

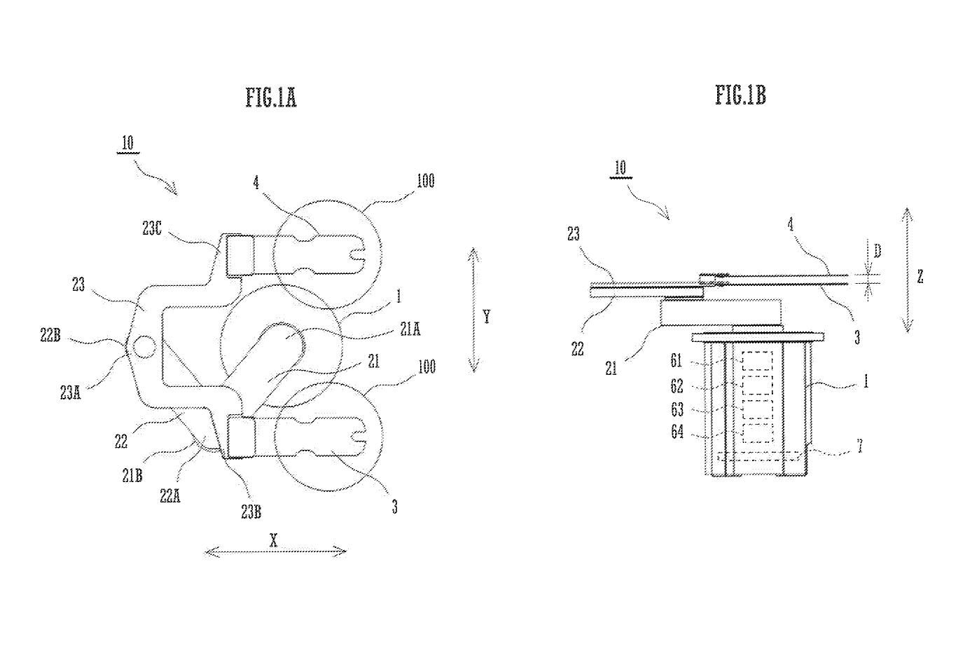

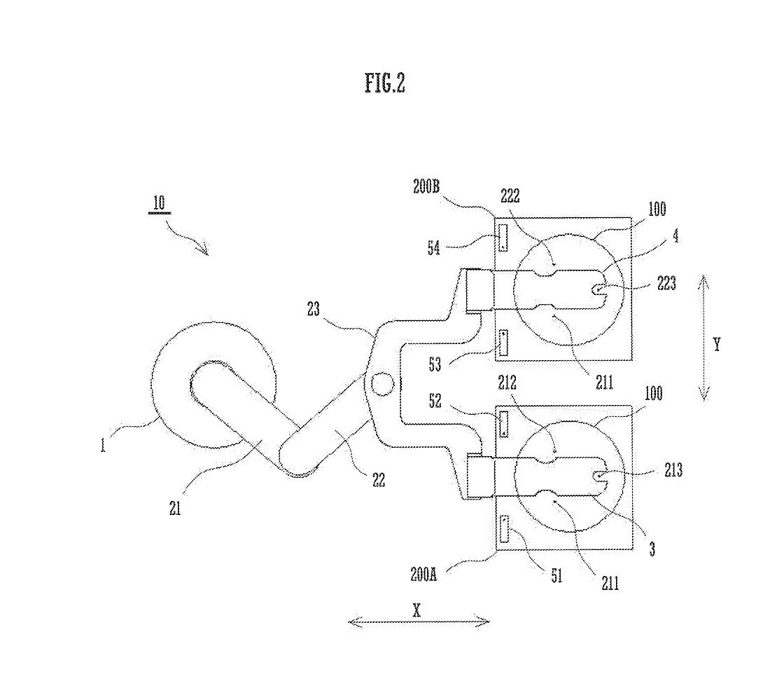

As shown in FIG. 1A, FIG. 1B and FIG. 2, a wafer transport apparatus 10 according to an embodiment of the present invention, which is applied to a semiconductor processing system not shown in the figure, transports, as an example, two wafers 100 respectively to two loading stages 200A and 200B at a time. Accordingly, the wafer transport apparatus 10 includes a main body 1, arms 21 to 23, wafer supports 3 and 4, and sensors 51 to 54.

The main body 1 houses therein swing motors 61 to 63, an elevating motor 64, and a control unit 7. The arms 21 to 23 configure a handling arm of the present invention. A first end 21A of the arm 21 is rotatably and liftably supported on the main body 1. A first end 22A of the arm 22 is rotatably supported on a second end 21B of the arm 21. A middle portion 23A of the arm 23 is rotatably supported on a second end 22B of the arm 22.

Wafer supports 3 and 4 are mounted on ends 23B and 23C of the arm 23, respectively, so as to be apart from each other by a distance Din a vertical direction. The wafer support 3 is positioned lower than the wafer support 4. Each of the wafer supports 3 and 4 holds a single wafer 100 placed on an upper surface thereof.

The wafers 100 can be moved in an arrow X-direction and an arrow Y-direction in their respective main planes (in horizontal planes) together with the wafer supports 3 and 4 by appropriately driving the swing motors 61 to 63. Also, the wafers 100 can be ascended and descended in a Z-direction (a vertical direction) together with the wafer supports 3 and 4 by driving the elevating motor 64.

Each of the sensors 51 to 54 is configured, for example, by a photoelectric sensor which outputs an ON signal when a wafer 100 shields between a light emitting element and a light receiving element. The sensors 51 to 54 correspond to a plurality of detection units in the present invention. The sensors 51 and 52 are disposed at the loading stage 200A to detect the wafer 100 placed on the wafer support 3. The sensors 53 and 54 are disposed at the loading stage 200B to detect the wafer 100 placed on the wafer support 4.

Three pins 211 to 213 are disposed at the loading stage 200A. The wafer 100 placed on the wafer support 3 is loaded onto the pins 211 to 213. Three pins 221 to 223 are disposed at the loading stage 200B. The wafer 100 placed on the wafer support 4 is loaded onto the pins 221 to 223.

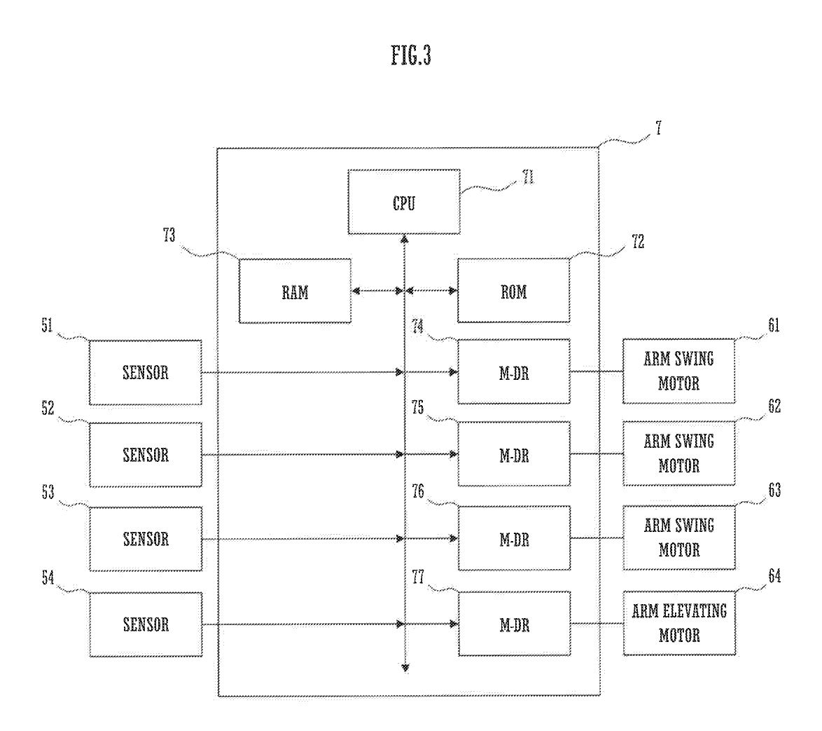

As shown in FIG. 3, the control unit 7 is configured by connecting a CPU 71 with a ROM 72, a RAM 73, and motor drivers 74 to 77. Detection signals of the sensors 51 to 54 are inputted to the CPU 71. Based on the detection signals of the sensors 51 to 54, the CPU 71 outputs drive data to the motor drivers 74 to 77 according to a program having been preliminarily written in the ROM 72. Data inputted to and outputted from the CPU 71 during this time are temporarily stored in the RAM 73. The motor drivers 74 to 77 drive the motors 61 to 64, respectively, in response to the drive data supplied from the CPU 71.

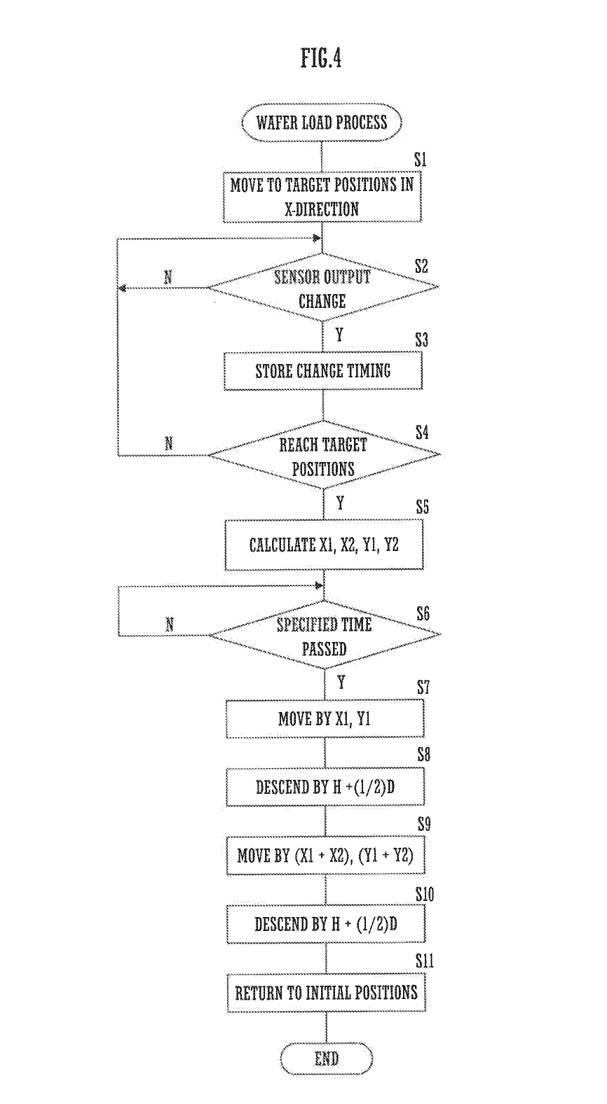

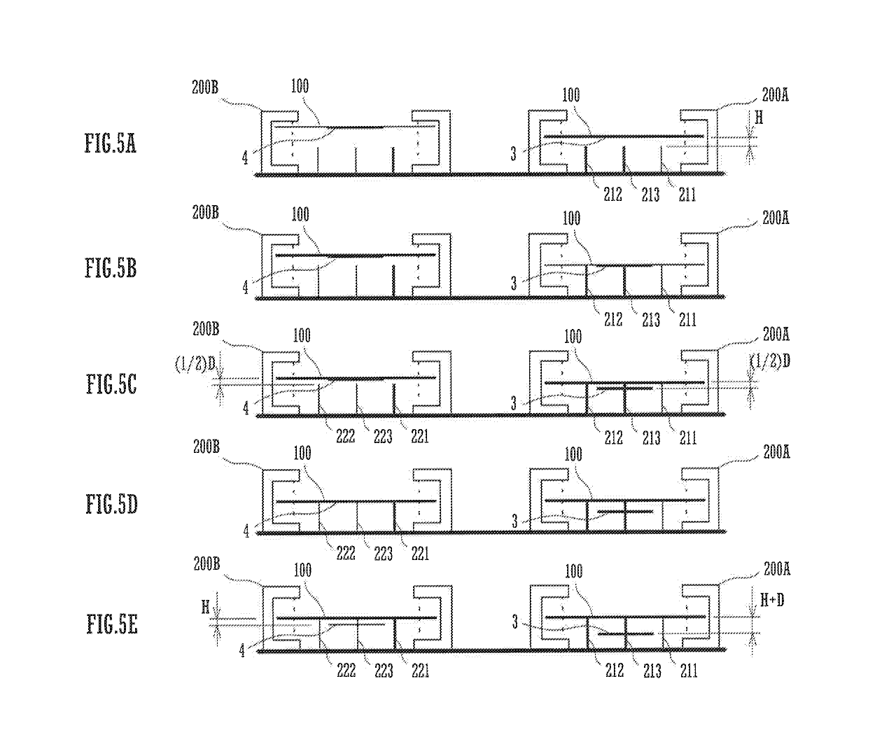

As shown in FIG. 4, during a wafer loading process in which two wafers 100 are respectively loaded to the loading stages 200A and 200B, the CPU 71 drives the motors 61 to 63 to move the wafer supports 3 and 4 along the X-direction toward predetermined target positions (Step S1). At this time, as shown in FIG. 5A, the wafer support 3 is kept at a position higher by a specified height H than upper ends of the pins 211 to 213. The CPU 71 detects ON/OFF changes of the respective outputs of the sensors 51 to 54 (Step S2), and sequentially stores the timings of the output changes in a specified memory area of the RAM 73 (Step S3).

When the wafer supports 3 and 4 reach the target positions (Step S4), the CPU 71 calculates errors of a current position of the wafer support 3 in the X-direction and the Y-direction relative to its target position determined based on the timings of the output changes of the sensors 51 and 52, as correction values X1 and Y1, respectively. Also, the CPU 71 calculates errors of a current position of the wafer support 4 in the X-direction and the Y-direction relative to its target position determined based on the timings of the output changes of the sensors 53 and 54, as correction values X2 and Y2, respectively. The CPU 71 stores the calculated correction values X1, Y1, X2 and Y2 in the RAM 73 (Step S5).

When a specified period of time has passed from the time when the wafer supports 3 and 4 had reached their target positions (Step S6), the CPU 71 drives the motors 61 to 63 to move the wafer support 3 together with the wafer support 4 in the X-direction and the Y-direction by the correction values X1 and Y1, respectively (Step S7), and drives the motor 64 to descend the wafer support 3 together with the wafer support 4 in the Z-direction by a height calculated by adding ½ of the distance D to the specified height H (Step S8).

By this operation, as shown in FIG. 5B and FIG. 5C, the wafer 100 placed on the wafer support 3 is loaded onto the pins 211 to 213 in a state accurately positioned at its target position in its main plane at the loading stage 200A. At this time, the wafer support 3 is at a position lower by (½)D than the upper ends of the pins 211 to 213. The wafer support 4 on which the other wafer 100 is placed is at a position higher by (½)D than upper ends of the pins 221 to 223 in the loading stage 200B.

Then, the CPU 71 drives the motors 61 to 63 to move the wafer support 4 together with the wafer support 3 in the X-direction and the Y-direction by correction values X1+X2 and Y1+Y2, respectively (Step S9), and drives the motor 64 to descend the wafer support 4 together with the wafer support 3 in the Z-direction by the height calculated by adding ½ of the distance D to the specified height H (Step S10).

By this operation, as shown in FIG. 5D and FIG. 5E, the wafer 100 placed on the wafer support 4 is loaded onto the pins 221 to 223 in a state accurately positioned at its target position in its main plane at the loading stage 200B. At this time, the wafer support 3 is at a position lower by H+D than the upper ends of the pins 211 to 213. The wafer support 4 is at a position lower by the height H than the upper ends of the pins 221 to 223 in the loading stage 200B.

After loading the two wafers 100 onto specified positions in the loading stages 200A and 200B, respectively, in the manner as described above, the CPU 71 drives the motors 61 to 64 to return the wafer supports 3 and 4 to their initial positions (Step S11), and ends the process.

As described above, the two wafers 100 can be accurately loaded onto the specified positions by transporting the two wafers 100 into the loading stages 200A and 200B, respectively, in the condition apart by a specified distance from each other in the vertical direction, and then subjecting the lower wafer 100 and the upper wafer 100 sequentially in this order to correction of position in the main plane and descending. Accordingly, it is not necessary to provide outside of the loading stages 200A and 200B any alignment device for correcting the position of each of the wafers 100 in its main plane.

Since it is not necessary to reciprocally move the wafers 100 between an alignment device and the loading stages 200A and 200B, the time required to load the two wafers 100 can be adequately reduced. Further, since it is not necessary to prepare a space for installing an alignment device, the wafer processing system can be down-sized.

Incidentally, the amount of descent of the wafer supports 3 and 4 at Step S10 and Step S12 may not be limited to H+(½)D, but may be an arbitrary value provided that the two wafers 100 placed on the wafer supports 3 and 4 can be sequentially placed on the pins 211 to 213 and the pins 221 to 223.

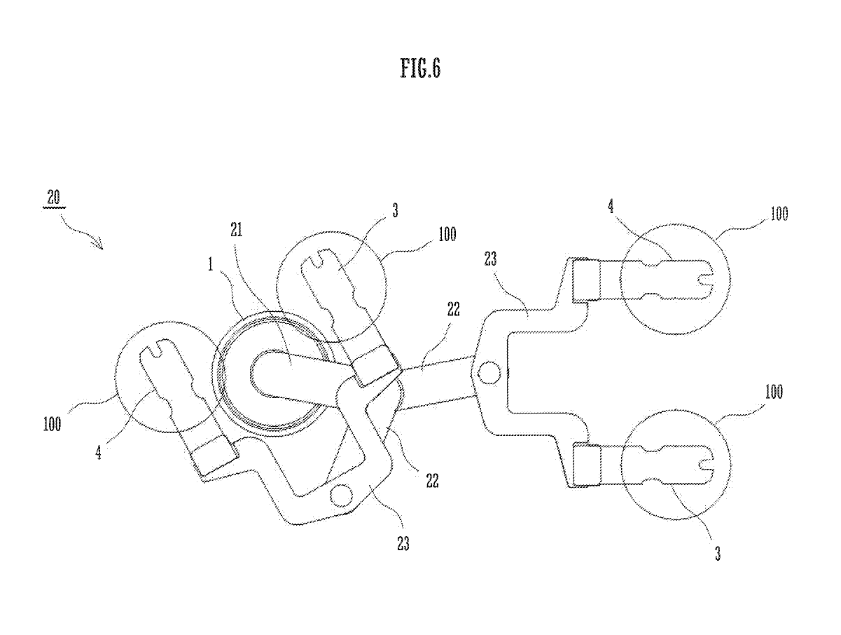

As shown in FIG. 6, a wafer transport apparatus 20 according to a second embodiment of the present invention has two sets of arms 22 and 23 and wafer supports 3 and 4. While the first set of wafer supports 3 and 4 unloads two wafers 100 having been processed from the loading stages 200A and 200B, the second set of wafer supports 3 and 4 can load unprocessed two wafers 100 to the loading stages 200A and 200B.

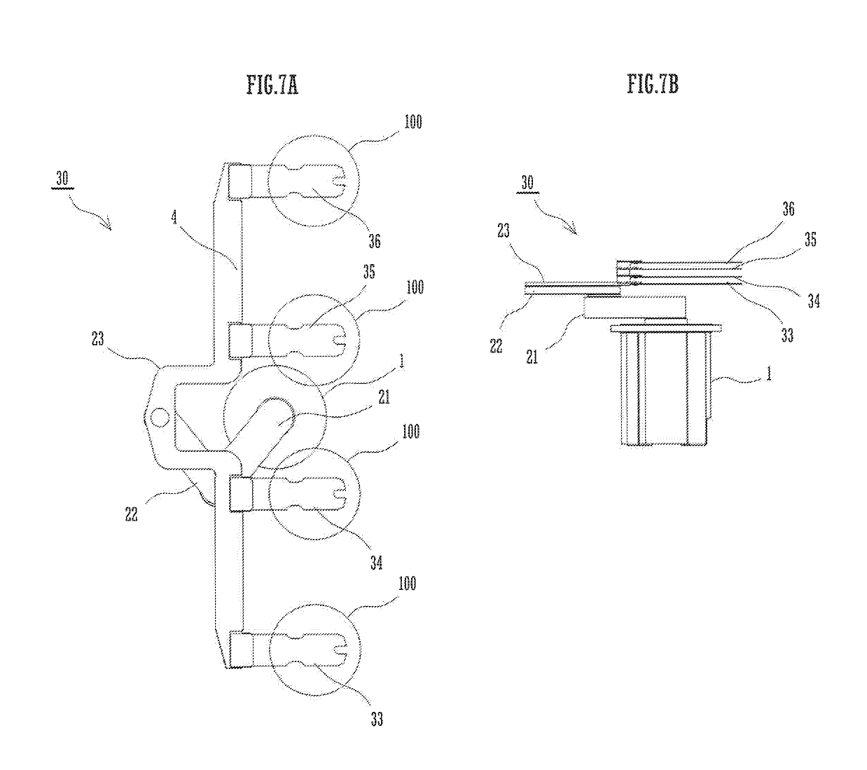

As shown in FIG. 7A and FIG. 7B, a wafer transport apparatus 30 according to a third embodiment of the present invention has four wafer supports 33 to 36 mounted on the arm 23 at intervals in the vertical direction. It is possible to load four wafers 100 onto respective specified positions of four loading stages by correcting the positions of the wafers in their main planes sequentially from a wafer 100 placed on a lower wafer support.

It should be understood that the embodiments described above are exemplifications in all respects, and are not limitative. Scope of the present invention is defined, not in the above-described embodiments, but in the accompanying claims. Further, it is intended that the scope of the present invention includes any modifications within the meaning and scope of the claims and equivalents thereof.

### REFERENCE SIGNS LIST

1 main body
3, 4 wafer support
7 control unit
10 wafer transport apparatus
21 to 23 arm
51 to 54 sensor
61 to 63 swing motor
64 elevating motor
100 wafer
200A, 200B loading stage

1. A wafer transport apparatus for transporting a plurality of wafers to a plurality of loading stages at a time, the wafer transport apparatus comprising:
a main body;
a handling arm supported on the main body movably at least in a main plane of each of the wafers;
a plurality of wafer supports each being supported on the handling arm and holding a single wafer;
a plurality of detection units for detecting positions of the wafers in their main planes at the plurality of loading stages, respectively; and
a control unit for correcting positions in the main planes of the wafers respectively held by the plurality of wafer supports sequentially at different heights from one another at the loading stages based on detection results of the detection units.

2. The wafer transport apparatus according to claim 1, wherein the control unit corrects the plurality of wafers sequentially from a lower position.

3. The wafer transport apparatus according to claim 2, wherein the handling arm is liftably supported on the main body, and supports the plurality of wafer supports at different heights from one another.
